(19) United States
(12) Patent Application Publication
(10) Pub. No.: US 2026/0303087 A1
(43) Pub. Date: Oct. 1, 2026

(54) POWER-ON RESET CIRCUIT

(71) Applicant: Huahong Integrated Circuit(Chengdu) Corporation, Chengdu City (CN)

(72) Inventors: Chen CHEN, Chengdu City (CN); Zhili WANG, Chengdu City (CN); Yifei QIAN, Chengdu City (CN)

(73) Assignee: Huahong Integrated Circuit(Chengdu) Corporation, Chengdu City (CN)

(21) Appl. No.: 19/565,346

(22) Filed: Mar. 12, 2026

(30) Foreign Application Priority Data
Mar. 31, 2025 (CN) 202510392989.3

(51) Int. Cl. H03K 17/22; H03K 3/037

(52) U.S. Cl. CPC H03K 17/223; H03K 3/037

(57) ABSTRACT

The present disclosure discloses a power-on reset circuit. A sixth PMOS transistor and a second resistor are added based on an existing power-on reset circuit structure. The sixth PMOS transistor is positioned in a branch of first PMOS transistor-zero^{th} NMOS transistor, and a second resistor is positioned in a branch of zero^{th} PMOS transistor-zero^{th} resistor-first resistor. It may be ensured that a normal function of the power-on reset circuit to detect a voltage of a power supply is not affected, and the branch of first PMOS transistor-zero^{th} NMOS transistor is turned off after a voltage of a power supply is established to reduce overall power consumption of the power-on reset circuit.

### CROSS-REFERENCE TO RELATED APPLICATIONS

This application claims priority to Chinese patent application No. 2025103929893, filed on Mar. 31, 2025, the disclosure of which is incorporated herein by reference in its entirety.

### TECHNICAL FIELD

The present disclosure relates to the field of semiconductor integrated circuits, and in particular, to a power-on reset circuit.

### BACKGROUND

With the rapid development of semiconductor technology, a circuit system inside a portable device is becoming more and more complex, and power consumption of a circuit is highly required. High power consumption often causes heating of the device, thereby affecting stability and a life of the device. A low-power design may enable the device to work for a long time after a charge, improving user experience, and enabling significant competitive advantages relative to the same style product.

A power-on reset (POR) circuit is often used in a microcontroller (MCU) to detect power-on of a power supply. Upon the powder-on of the power supply, the POR circuit generates a RESET/RESETB pulse output signal to an internal digital module of a chip to ensure that the chip always works in a determined state.

A structure of an existing POR circuit is shown in FIG. 1.

In a power-on phase of a power supply, a voltage of a first node V1 rises along with a power supply voltage, a voltage of an output terminal V1B of a first inverter remains low, a third PMOS transistor PM3 is turned off, and a fourth PMOS transistor PM4 is turned on. At this time, a voltage VGN of a gate terminal of a zero^{th} NMOS transistor NM0 is a voltage component of a first resistor R1 in a branch of a zero^{th} PMOS transistor PM0-zero^{th} resistor R0-first resistor R1. As the power supply voltage increases, when the voltage VGN of the gate terminal of the zero^{th} NMOS transistor reaches a voltage slightly higher than a threshold voltage of the zero^{th} NMOS transistor NM0, the voltage of the first node V1 is pulled down, the voltage of the first inverter output terminal V1B is high, the third PMOS transistor PM3 is turned on, the fourth PMOS transistor PM4 is turned off, a voltage of a second node V2 is set low, and a branch of second PMOS transistor PM2-fifth PMOS transistor PM5 charges a reset capacitor C0. When a voltage of an upper plate V3 of the reset capacitor C0 is high enough, a RESET/RESETB (low-level reset/high-level reset) signal is flipped. At this time, the power supply voltage is a power-on detection point. A voltage of the power-on detection point is about a sum of a threshold voltage of the zero^{th} PMOS transistor PM0, a threshold voltage of the zero^{th} NMOS transistor NM0, and a voltage across two ends of the zero^{th} resistor R0.

In a power-off phase of a power supply, the voltage of the first node V1 is set low, and a voltage of an output terminal V1B of the first inverter follows the power supply voltage. At this time, the third PMOS transistor PM3 is turned on, the voltage VGN of the gate terminal of the zero^{th} NMOS transistor changes with the power supply voltage, and the fourth PMOS transistor PM4 is turned off. When the power supply voltage is slightly lower than the threshold voltage of the zero^{th} NMOS transistor NM0, the voltage of the first node V1 is raised, the voltage of the output terminal V1B of the first inverter is low, and the voltage of the second node V2 is high. At this time, the first NMOS transistor NM1 is turned on, the voltage of the upper plate V3 of the reset capacitor C0 is pulled down, and the RESET/RESETB (low-level RESET/high-level RESET) signal is flipped. At this time, the power supply voltage is a power-off detection point. A voltage of the power-off detection point is about the threshold voltage of the zero^{th} NMOS transistor NM0.

From the above circuit analysis, it can be seen that after the power-on of the power supply and the POR circuit works normally, power consumption of a whole circuit is determined by the branch of zero^{th} PMOS transistor PM0-zero^{th} resistor R0-first resistor R1 and the branch of first PMOS transistor PM1-zero^{th} NMOS transistor NM0 that normally operates, wherein the zero^{th} PMOS transistor PM0 and the first PMOS transistor PM1 are a pair of current mirrors. The two normally operated branches increase overall power consumption of the POR circuit.

### BRIEF SUMMARY

A power-on reset circuit provided in the present disclosure includes a zero^{th} PMOS transistor PM0, a first PMOS transistor PM1, a second PMOS transistor PM2, a third PMOS transistor PM3, a fourth PMOS transistor PM4, a fifth PMOS transistor PM5, a sixth PMOS transistor PM6, a zero^{th} NMOS transistor NM0, a first NMOS transistor NM1, a zero^{th} resistor R0, a first resistor R1, a second resistor R2, a first inverter INV1, a second inverter INV2, a third inverter INV3, and a reset capacitor C0.

Source terminals of the zero^{th} PMOS transistor PM0, the first PMOS transistor PM1, the second PMOS transistor PM2, and the third PMOS transistor PM3 are connected to a power supply voltage VDD.

The second resistor R2, the zero^{th} resistor R0, and the first resistor R1 are sequentially connected in series between the third node VP1 and ground GND.

The zero^{th} PMOS transistor PM0 has a drain terminal connected to the third node VP1 and a gate terminal connected to a gate terminal of the first PMOS transistor PM1, a gate terminal of the second PMOS transistor PM2, and a series connection point VP between the second resistor R2 and the zero^{th} resistor R0.

A drain terminal of the first PMOS transistor PM1 is connected to a source terminal of the sixth PMOS transistor PM6.

The sixth PMOS transistor PM6 has a drain terminal connected to a first node V1 and a gate terminal connected to the third node VP1.

The third PMOS transistor PM3 has a gate terminal connected to the first node V1 and a drain terminal connected to a drain terminal of the fourth PMOS transistor PM4 and a gate terminal of the zero^{th} NMOS transistor NM0.

The fourth PMOS transistor PM4 has a source terminal connected to a series connection point between the zero^{th} resistor R0 and the first resistor R1, and a gate terminal connected to an output terminal V1B of the first inverter INV1.

The zero^{th} NMOS transistor NM0 has a source terminal that is connected to the ground GND and a drain terminal connected to the first node V1.

The first inverter INV1 and the second inverter INV2 are sequentially connected in series between the first node V1 and a second node V2.

A drain terminal of the second PMOS transistor PM2 is connected to the source terminal of the fifth PMOS transistor PM5.

The fifth PMOS transistor PM5 has a gate terminal connected to the second node V2 and a gate terminal of the first NMOS transistor NM1, and a drain terminal connected to a drain terminal of the first NMOS transistor NM1 and an upper plate V3 of the reset capacitor C0.

A source terminal of the first NMOS transistor NM1 is connected to the ground GND.

A lower plate of the reset capacitor C0 is connected to the ground GND.

The third inverter INV3 has an input terminal connected to the upper plate V3 of the reset capacitor C0 and an output terminal used for outputting a low-level reset signal RESET.

In some embodiments, the power-on reset circuit further includes a buffer BUFF.

The input terminal of the buffer BUFF is connected to the upper plate V3 of the reset capacitor C0, and the output terminal is used for outputting a high-level reset signal RESETB.

The gate terminal of the sixth PMOS transistor PM6 is set to be connected to the output terminal V1B of the first inverter, the upper plate of V3 of the reset capacitor C0, or the output terminal of the buffer BUFF.

According to the power-on reset (POR) circuit of the present disclosure, during a power-on phase of a power supply, when the power supply voltage VDD is near a power-on detection point, a current flowing through the zero^{th} PMOS transistor PM0 is relatively small. At this point, a voltage of the third node VP1 differs slightly from a voltage of a series connection point VP between the second resistor R2 and the zero^{th} resistor R0. The sixth PMOS transistor PM6 is turned on. The power-on reset (POR) circuit's power-on detection function is not affected, and the low-level reset signal RESET is flipped normally. When the power-on of the power supply voltage VDD is completed, a stable current flows through the zero^{th} PMOS transistor PM0. At this point, a voltage of the third node VP1 is equal to a voltage of a series connection point VP between the second resistor R2 and the zero^{th} resistor R0, plus a product of a current I_{PM0} flowing through the zero^{th} PMOS transistor PM0 and a resistance value of the second resistor R2 (V_{P1}=V_{P}+I_{PM0}*R₂). The sixth PMOS transistor PM6 is turned off. A branch of first PMOS transistor PM1-zero^{th} NMOS transistor NM0 is turned off. Overall power consumption of the power-on reset (POR) circuit is reduced. During powder-off of the powder supply, when the power supply voltage VDD is near a power-off detection point, a current flowing through the zero^{th} PMOS transistor PM0 is relatively small. At this point, the voltage of the third-stage node VP1 slightly differs from the voltage of the series connection point between the second resistor R2 and the zero^{th} resistor R0. The sixth PMOS transistor PM6 is turned on. A power-on detection function of the power-on reset (POR) circuit is not affected. The low-level reset signal RESET is flipped normally.

### BRIEF DESCRIPTION OF THE DRAWINGS

To describe technical solutions of the present disclosure more clearly, the following briefly describes drawings required for describing the present disclosure. Apparently, the drawings in the following description merely show some embodiments of the present disclosure, and a person of ordinary skill in the art may derive other drawings from these drawings without creative efforts.

FIG. 1 shows an existing power-on reset circuit;

FIG. 2 is a circuit diagram according to an embodiment of a power-on reset circuit in the present disclosure; and

FIG. 3 shows a comparison of simulation results for the power-on reset circuits shown in FIG. 1 and FIG. 2.

### DETAILED DESCRIPTION OF THE DISCLOSURE

Technical solutions in embodiments of the present disclosure are clearly and completely described below with reference to accompanying drawings in the embodiments of the present disclosure. Apparently, the described embodiments are merely some rather than all of the embodiments of the present disclosure. Based on the embodiments of the present disclosure, all other embodiments obtained by a person of ordinary skill in the art without creative efforts fall within the protection scope of the present disclosure. “First”, “second”, and similar terms used in this application do not indicate any order, quantity or significance, but are used to only distinguish between different components. A similar term, such as “include” or “comprise”, means that an element or object appearing before the term covers an element or object listed after the term and equivalents thereof, but do not exclude other elements or objects. Similar terms such as “connection” or “connected” are not limited to a physical or mechanical connection, but may also include an electrical connection, whether direct or indirect. Terms such as “up”, “down”, “left”, and “right” are only used to indicate a relative positional relationship. When an absolute position of the described object changes, the relative positional relationship may also change accordingly.

It is to be noted that the embodiments in the present disclosure and features in the embodiments may be combined with each other in case of no conflicts.

### Embodiment I

Referring to FIG. 2, a power-on reset circuit includes a zero^{th} PMOS transistor PM0, a first PMOS transistor PM1, a second PMOS transistor PM2, a third PMOS transistor PM3, a fourth PMOS transistor PM4, a fifth PMOS transistor PM5, a sixth PMOS transistor PM6, a zero^{th} NMOS transistor NM0, a first NMOS transistor NM1, a zero^{th} resistor R0, a first resistor R1, a second resistor R2, a first inverter INV1, a second inverter INV2, a third inverter INV3, and a reset capacitor C0.

Source terminals of the zero^{th} PMOS transistor PM0, the first PMOS transistor PM1, the second PMOS transistor PM2, and the third PMOS transistor PM3 are connected to a power supply voltage VDD.

The second resistor R2, the zero^{th} resistor R0, and the first resistor R1 are sequentially connected in series between the third node VP1 and ground GND.

The zero^{th} PMOS transistor PM0 has a drain terminal connected to the third node VP1 and a gate terminal connected to a gate terminal of the first PMOS transistor PM1, a gate terminal of the second PMOS transistor PM2, and a series connection point VP between the second resistor R2 and the zero^{th} resistor R0.

A drain terminal of the first PMOS transistor PM1 is connected to a source terminal of the sixth PMOS transistor PM6.

The sixth PMOS transistor PM6 has a drain terminal connected to a first node V1, and a gate terminal connected to the third node VP1.

The third PMOS transistor PM3 has a gate terminal connected to the first node V1 and a drain terminal connected to a drain terminal of the fourth PMOS transistor PM4, and a gate terminal of the zero^{th} NMOS transistor NM0.

The fourth PMOS transistor PM4 has a source terminal connected to a series connection point between the zero^{th} resistor R0 and the first resistor R1, and a gate terminal connected to an output terminal V1B of the first inverter INV1.

The zero^{th} NMOS transistor NM0 has a source terminal that is connected to the ground GND and a drain terminal connected to the first node V1.

The first inverter INV1 and the second inverter INV2 are sequentially connected in series between the first node V1 and a second node V2.

A drain terminal of the second PMOS transistor PM2 is connected to the source terminal of the fifth PMOS transistor PM5.

The fifth PMOS transistor PM5 has a gate terminal connected to the second node V2 and a gate terminal of the first NMOS transistor NM1, and a drain terminal connected to a drain terminal of the first NMOS transistor NM1 and an upper plate V3 of the reset capacitor C0.

A source terminal of the first NMOS transistor NM1 is connected to the ground GND.

A lower plate of the reset capacitor C0 is connected to the ground GND.

The third inverter INV3 has an input terminal connected to the upper plate V3 of the reset capacitor C0 and an output terminal used for outputting a low-level reset signal RESET.

The power-on reset circuit may be used as a power-on reset circuit used in a microcontroller (MCU).

According to the power-on reset (POR) circuit in Embodiment I, during a power-on phase of a power supply, when the power supply voltage VDD is near a power-on detection point, a current flowing through the zero^{th} PMOS transistor PM0 is relatively small. At this point, a voltage of the third node VP1 differs slightly from a voltage of a series connection point VP between the second resistor R2 and the zero^{th} resistor R0. The sixth PMOS transistor PM6 is turned on. The power-on reset (POR) circuit's power-on detection function is not affected, and the low-level reset signal RESET is flipped normally. When the power-on of the power supply voltage VDD is completed, a stable current flows through the zero^{th} PMOS transistor PM0. At this point, a voltage of the third node VP1 is equal to a voltage of a series connection point VP between the second resistor R2 and the zero^{th} resistor R0, plus a product of a current I_{PM0} flowing through the zero^{th} PMOS transistor PM0 and a resistance value of the second resistor R2 (V_{P1}=V_{P}+I_{PM0}*R₂). The sixth PMOS transistor PM6 is turned off. A branch of first PMOS transistor PM1-zero^{th} NMOS transistor NM0 is turned off. Overall power consumption of the power-on reset (POR) circuit is reduced. During power-off of the power supply, when the power supply voltage VDD is near a power-off detection point, a current flowing through the zero^{th} PMOS transistor PM0 is relatively small. At this point, the voltage of the third-stage node VP1 slightly differs from the voltage of the series connection point between the second resistor R2 and the zero^{th} resistor R0. The sixth PMOS transistor PM6 is turned on. A power-on detection function of the power-on reset (POR) circuit is not affected. The low-level reset signal RESET is flipped normally.

From the above analysis, it can be seen that an appropriate size of the sixth PMOS transistor and a resistance value of the second resistor R2 are selected, so that overall circuit power consumption can be reduced by turning off one normally operated branch of the power-on reset (POR) circuit when the power-on of the power supply voltage VDD is completed without affecting the normal function of the power-on reset (POR) circuit.

The power-on reset circuit in Embodiment I is improved based on the existing power-on reset circuit. A PMOS transistor (the sixth PMOS transistor) and a resistor (the second resistor R2) are added. The sixth PMOS transistor PM6 is positioned in a branch of first PMOS transistor PM1-zero^{th} NMOS transistor NM0, and a second resistor R2 is positioned in a branch of zero^{th} PMOS transistor PM0-zero^{th} resistor R0-first resistor R1. It may be ensured that a normal function of the power-on reset circuit to detect a voltage of a power supply is not affected. After a power supply voltage is fully established (the power-on reset circuit works to generate a pulse output signal), one of normally operated branches (the branch of first PMOS transistor PM1-zero^{th} NMOS transistor NM0) is turned off, thereby achieving a purpose of reducing overall power consumption of the power-on reset (POR) circuit.

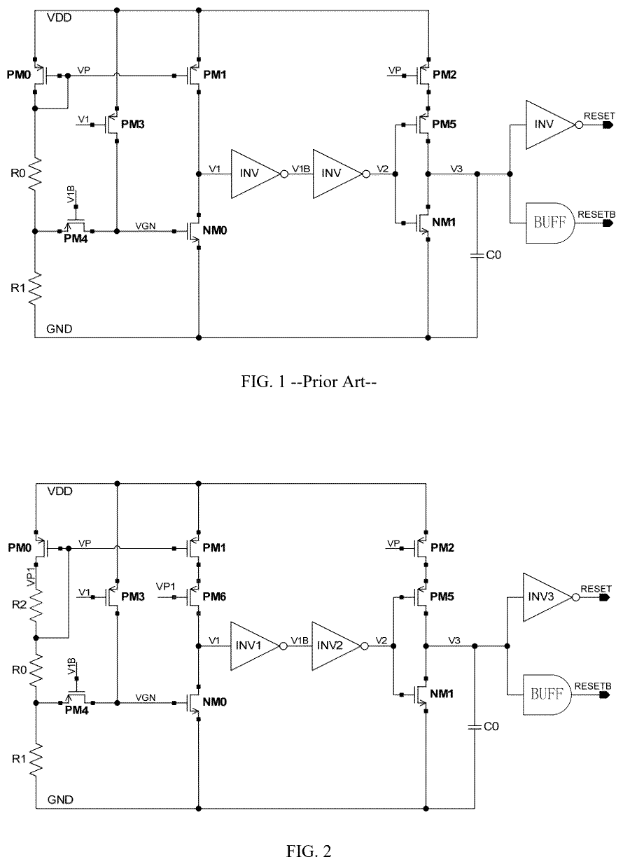

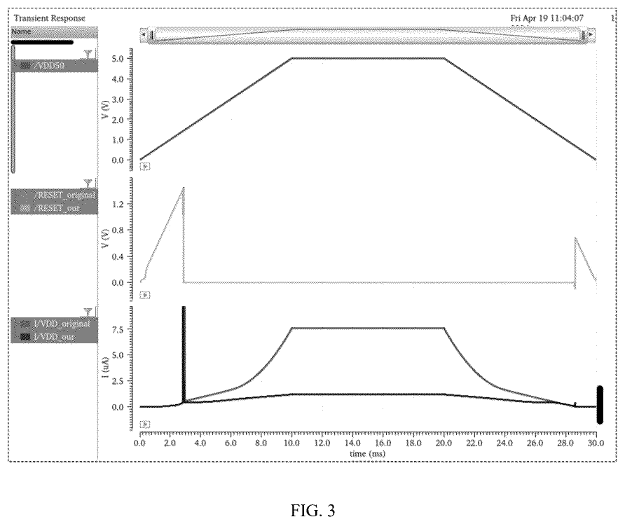

The power-on reset circuit of Embodiment I has been verified by circuit designs and Virtuoso simulation. Comparison of simulation results of the power-on reset circuit structure shown in FIG. 1 and the low-power power-on reset circuit shown in FIG. 2 is shown in FIG. 3.

The power supply power-on/power-off simulation result for the existing power-on reset circuit structure shown in FIG. 1 is represented by a suffix ‘original’ in FIG. 3. The power-on reset circuit functions normally, in which a power-on detection point is about 1.4 V and a power-off detection point is about 0.7 V. After a power supply voltage is stable, overall power consumption of the circuit is about 7.5 uA.

The power-on/power-off simulation result of the low-power-on reset circuit structure of the present disclosure shown in FIG. 2 is represented by a suffix ‘our’ in FIG. 3. Under the same simulation condition, the low-power consumption power-on reset circuit functions normally, where a power-on detection point is about 1.4 V, a power-off detection point is about 0.7 V. They are basically the same as those for the existing power-on reset circuit. After the power supply voltage is stable, the branch of first PMOS transistor PM1-zero^{th} NMOS transistor NM0 is turned off. Overall power consumption of the circuit is about 1.2 uA.

### Embodiment II

Based on embodiment I, the power-on reset circuit further includes a buffer BUFF.

The input terminal of the buffer BUFF is connected to the upper plate V3 of the reset capacitor C0, and the output terminal is used for outputting a high-level reset signal RESETB.

It is noted that the gate terminal of the sixth PMOS transistor PM6 is not limited to being connected to a signal of the third node VP1, and may also be set to be connected to a signal of the output terminal V1B of the first inverter, a signal of the upper plate of V3 of the reset capacitor C0 or a signal of the output terminal of the buffer BUFF (RESETB).

### Embodiment III

Based on the power-on reset circuit of Embodiment II, source-drain turn-on resistance of the third PMOS transistor PM3 is smaller than source-drain turn-on resistance of the zero^{th} PMOS transistor PM0, the first PMOS transistor PM1, the second PMOS transistor PM2, and the fifth PMOS transistor PM5.

Preferably, source-drain turn-on resistance of the fourth PMOS transistor PM4 is smaller than source-drain turn-on resistance of the zero^{th} PMOS transistor PM0, the first PMOS transistor PM1, the second PMOS transistor PM2, and the fifth PMOS transistor PM5.

Preferably, source-drain turn-on resistance of the third PMOS transistor PM3 is less than 2 KΩ.

Preferably, the source-drain turn-on resistance of the zero^{th} PMOS transistor PM0, the resistance of the zero^{th} resistor R0, the resistance of the first resistor R1, and the resistance of the second resistor R2 are of the same magnitude.

Preferably, resistance values of the zero^{th} resistor R0, the first resistor R1, and the second resistor R2 range from 10 KΩ to 10 MΩ.

Preferably, process parameters of the second PMOS transistor PM2 are the same as those of the zero^{th} PMOS transistor PM0.

Preferably, the capacitance value of the reset capacitor C0 ranges from 0.01 pF to 100 pF.

Preferably, the reset capacitor C0 is a MOS capacitor, a MOM capacitor, or a variable capacitor.

The power-on reset circuit in Embodiment III may further adjust a voltage component of a resistor by adjusting a resistance value of the second resistor R2 to further adjust a power-on detection point of a voltage, control a power-off detection point to a lower voltage, and further, can flexibly adjust a pulse width of reset signals RESET/RESETB, enabling high design flexibility and expanding an application range of the existing circuit.

The above descriptions are merely preferred embodiments of the present disclosure and are not intended to limit the present disclosure. Any modification, equivalent replacement, or improvement made within the spirit and principle of the present disclosure shall fall within the protection scope of the present disclosure.

1. A power-on reset circuit, comprising a zero^{th} PMOS transistor, a first PMOS transistor, a second PMOS transistor, a third PMOS transistor, a fourth PMOS transistor, a fifth PMOS transistor, a sixth PMOS transistor, a zero^{th} NMOS transistor, a first NMOS transistor, a zero^{th} resistor, a first resistor, a second resistor, a first inverter, a second inverter, a third inverter, and a reset capacitor,
wherein source terminals of the zero^{th} PMOS transistor, the first PMOS transistor, the second PMOS transistor, and the third PMOS transistor are connected to a power supply voltage;
the second resistor, the zero^{th} resistor, and the first resistor are sequentially connected in series between the third node and ground;
the zero^{th} PMOS transistor has a drain terminal connected to the third node and a gate terminal connected to a gate terminal of the first PMOS transistor, a gate terminal of the second PMOS transistor, and a series connection point between the second resistor and the zero^{th} resistor;
a drain terminal of the first PMOS transistor is connected to a source terminal of the sixth PMOS transistor;
the sixth PMOS transistor has a drain terminal connected to a first node and a gate terminal connected to the third node;
the third PMOS transistor has a gate terminal connected to the first node, and a drain terminal connected to a drain terminal of the fourth PMOS transistor and a gate terminal of the zero^{th} NMOS transistor;
the fourth PMOS transistor has a source terminal connected to a series connection point between the zero^{th} resistor and the first resistor, and a gate terminal connected to an output terminal of the first inverter;
the zero^{th} NMOS transistor has a source terminal that is connected to the ground and a drain terminal connected to the first node;
the first inverter and the second inverter are sequentially connected in series between the first node and a second node;
a drain terminal of the second PMOS transistor is connected to the source terminal of the fifth PMOS transistor;
the fifth PMOS transistor has a gate terminal connected to the second node and a gate terminal of the first NMOS transistor, and a drain terminal connected to a drain terminal of the first NMOS transistor and an upper plate of the reset capacitor;
a source terminal of the first NMOS transistor is connected to the ground;
a lower plate of the reset capacitor is connected to the ground; and
the third inverter has an input terminal connected to the upper plate of the reset capacitor, and an output terminal used for outputting a low-level reset signal.

2. The power-on reset circuit according to claim 1, wherein
the power-on reset circuit further comprises a buffer; and
an input terminal of the buffer is connected to the upper plate of the reset capacitor, and the output terminal is used for outputting a high-level reset signal.

3. The power-on reset circuit according to claim 1, wherein source-drain turn-on resistance of the third PMOS transistor is smaller than source-drain turn-on resistance of the zero^{th} PMOS transistor, the first PMOS transistor, the second PMOS transistor, and the fifth PMOS transistor.

4. The power-on reset circuit according to claim 1, wherein source-drain turn-on resistance of the fourth PMOS transistor is smaller than source-drain turn-on resistance of the zero^{th} PMOS transistor, the first PMOS transistor, the second PMOS transistor, and the fifth PMOS transistor.

5. The power-on reset circuit according to claim 1, wherein the source-drain turn-on resistance of the third PMOS transistor is less than 2 KΩ.

6. The power-on reset circuit according to claim 1, wherein the source-drain turn-on resistance of the zero^{th} PMOS transistor, the resistance of the zero^{th} resistor, the resistance of the first resistor, and the resistance of the second resistor are of the same magnitude.

7. The power-on reset circuit according to claim 1, wherein resistance values of the zero^{th} resistor, the first resistor, and the second resistor range from 10 KΩ to 10 MΩ.

8. The power-on reset circuit according to claim 1, wherein process parameters of the second PMOS transistor are the same as those of the zero^{th} PMOS transistor.

9. The power-on reset circuit according to claim 1, wherein The capacitance value of the reset capacitor ranges from 0.01 pF to 100 pF.

10. The power-on reset circuit according to claim 2, wherein the gate terminal of the sixth PMOS transistor is set to be connected to the output terminal of the first inverter, the upper plate of the reset capacitor, or the output terminal of the buffer.
